(19) United States
(12) Patent Application Publication
(10) Pub. No.: US 2007/0190673 A1
(43) Pub. Date: Aug. 16, 2007

(54) Organic light emitting diode and method of manufacturing the same

(76) Inventors: Ick-hwan Ko, Seoul (KR); Sung-kee Kang, Seongnam-si (KR); Jung-woo Kim, Yongin-si (KR); Ho-nyeon Lee, Seongnam-si (KR); Young-tea Chun, Suwon-si (KR); Hong-shik Shim, Seoul (KR)

Correspondence Address: CANTOR COLBURN, LLP, 55 GRIFFIN ROAD SOUTH, BLOOMFIELD, CT, 06002, US

(21) Appl. No.: 11/502,002

(22) Filed: Aug. 10, 2006

(30) Foreign Application Priority Data
Feb. 11, 2006 (KR) 10-2006-0013334

(51) Int. Cl. H01L 21/00

(52) U.S. Cl. 438/21

(57) ABSTRACT

An organic light emitting diode includes a plurality of bank portions and light emitting parts formed between the bank portions wherein the bank portions have stepwise portions at ends thereof extending to the light emitting parts. The exemplary embodiments of an organic light emitting diode according to the present invention have droplets deposited in a wider space between the bank portions, and adjacent pixels are prevented from contacting each other and being shorted out.

This application claims priority to Korean Patent Application No. 10-2006-0013334, filed on Feb. 11, 2006, and all the benefits accruing therefrom under 35 U.S.C. §119(a), the contents of which in its entirety are herein incorporated by reference.

### BACKGROUND OF THE INVENTION

1. Field of the Invention

The present invention relates to an organic light emitting diode and, more particularly, to an organic light emitting diode and a method of manufacturing the same, in which a structure of bank portions is improved to be advantageous when forming a light emitting part using an inkjet method.

2. Description of the Related Art

Generally, organic light emitting diode displays include an organic light emitting diode (“OLED”) deposited on a thin film transistor (“TFT”) of an electric circuit so that a light emitting part of the organic light emitting diode selectively emits light according to a signal under the control of the TFT.

In an organic light emitting diode display, electrodes and light emitting parts are laminated in a plurality of spaces partitioned by bank portions. Each of the plurality of spaces includes electrodes, namely an anode and a cathode, which are formed with a light emitting part therebetween to form a plurality of OLEDs. In each OLED an electrical passage is formed between the anode and the cathode through the light emitting part. Each of the light emitting parts forms a luminous spot corresponding to a single pixel of the display.

Therefore, when a current flows through the anode, the light emitting part and the cathode, conduction occurs, e.g., electrically charged particles move through a transmission medium. In this arrangement the light emitting part is part of the transmission medium. The light emitting layer has the property that energy is emitted in the form of light when holes and electrons are combined and excited therein. This light becomes the luminous spot corresponding to a single pixel of the display panel. The light emitting part may include hole transporting layers and emission layers.

An inkjet method of diluting a light emitting material with a solvent and depositing droplets of the resulting emission layer solution between the bank portions and then drying the droplets is widely used in forming the emission layer portion of the light emitting part of such an OLED. Similarly, an inkjet method of diluting a hole transporting material with a solvent and depositing droplets of the resulting hole transporting layer solution between the bank portions and then drying the droplets is widely used in forming the hole transporting layer portion of the light emitting part of such an OLED.

That is, as illustrated in FIG. 1 for example, electrodes 30 and bank portions 10 are formed firstly by photolithography and then droplets 20, which comprise one of the hole transporting layer solution and the emission layer solution, are deposited between the bank portions 10 through inkjet nozzles (not shown). The droplets 20 are a solution composed of a solute of one of the light emitting material and the hole transporting material comprising about 0.5% to about 2% of the volume of the final solution and a solvent comprising about 98% to about 99.5% of the final solution. The droplets 20 spread over the bank portions 10 as illustrated in FIG. 1. Thereafter, the solvent is evaporated through a drying process so a thin solute layer 20′ is formed on the electrodes 30 between the bank portions 10 as illustrated in FIG. 2. The thin solute layer 20′ forms one of the hole transporting layers or one of the emission layers. The other layers of the light emitting part are formed in turn by repeating the above-described processes.

During the formation of the light emitting or hole transporting layers, when the droplets 20 are deposited between the bank portions 10, the droplets 20 are formed in a convex shape as illustrated in FIG. 1. At this time, if the droplets 20 are increased in volume, the droplets 20 on adjacent pixels contact each other as illustrated in FIG. 3. This contact produces a high risk of electric shorts. The risk of electrical shorts may be diminished by reducing the concentration of the solvent included in each droplet 20. A droplet 20 with a reduced amount of solvent does not rise as high above the bank portions 10, and does not disperse as far laterally. However, when the concentration of solvent is reduced, the concentration of the light emitting part material in the droplets 20 correspondingly increases, and the flowing ability of the droplets 20 is reduced so that the inkjet nozzles may become plugged and malfunction.

Alternatively, a method of processing the surface of the bank portions 10 using plasma so as to enlarge a contacting angle θ of the droplets 20 may also reduce the chances of a contact between the droplets 20 on adjacent pixels. However, this method is less effective at preventing electrical shorts than the method of reducing the amount of solvent in the light emitting layer solution or the hole transporting layer solution.

Therefore, in order to solve this problem, a more reliable, less prone to malfunction method of preventing a contact between droplets on adjacent pixels is required.

### BRIEF SUMMARY OF THE INVENTION

The present invention provides an organic light emitting diode and a method of manufacturing the same, in which a structure of bank portions is improved so as to markedly reduce chances of a contact between droplets on adjacent pixels when forming light emitting parts using an inkjet method.

According to an exemplary embodiment of the present invention, there is provided an organic light emitting diode including a plurality of bank portions and light emitting parts formed between the bank portions, wherein the bank portions have stepwise portions at ends thereof extending to the light emitting part.

The light emitting part may include an emission layer and a hole transporting layer.

According to another exemplary embodiment of the present invention, there is provided a method of manufacturing an organic light emitting diode including; forming a plurality of bank portions and forming light emitting parts between the bank portions, wherein the forming of the bank portions includes forming a photoresist layer, preparing a mask having an exposing region, a shadowing region, and slits between the exposing region and the shadowing region, exposing the photoresist layer to an ultraviolet light source through the mask and developing the exposed photoresist layer to form bank portions having stepwise portions in a region corresponding to the slits.

The forming of the light emitting parts may include depositing a dilution of a light emitting part forming material in a solvent between the stepwise portions of the bank portions as a droplet and drying the droplet.

### BRIEF DESCRIPTION OF THE DRAWINGS

The above and other features and advantages of the present invention will become more apparent by describing exemplary embodiments thereof with reference to the attached drawings in which:

FIG. 1 and 2 are cross-sectional views illustrating layer forming processes of a conventional organic light emitting diode using an inkjet method;

FIG. 3 is a cross-sectional view illustrating an electrical shorting condition during a layer forming process of the conventional organic light emitting diode illustrated in FIG. 1;

FIG. 4 is a cross-sectional view illustrating an exemplary embodiment of a layer forming process of an organic light emitting diode according to the present invention in which droplets are dropped between bank portions; and

FIG. 5 is a cross-sectional view illustrating an exemplary embodiment of a process of forming a bank portion of the organic light emitting diode illustrated in FIG. 4 according to an embodiment of the present invention.

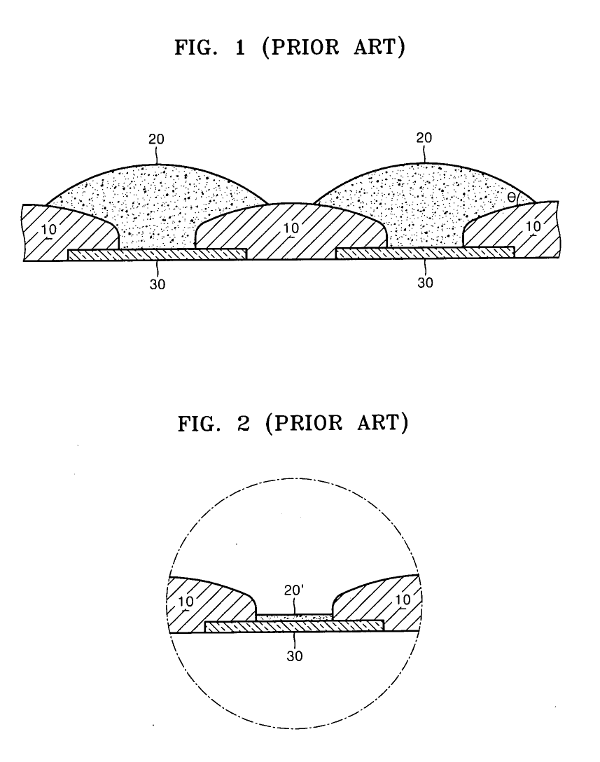

### DETAILED DESCRIPTION OF THE INVENTION

The present invention is described more fully hereinafter with reference to the accompanying drawings, in which exemplary embodiments of the present invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-section illustrations that are schematic illustrations of idealized exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

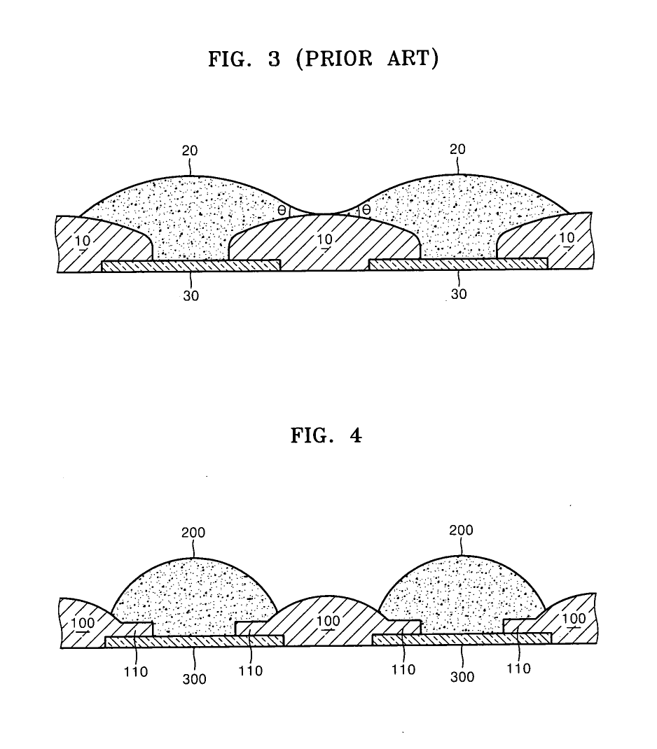

FIG. 4 is a cross-sectional view illustrating an exemplary embodiment of a layer forming process of an organic light emitting diode according to the present invention in which droplets 200 are dropped between bank portions 100.

As illustrated in FIG. 4, the organic light emitting diode is formed using an inkjet method including depositing droplets of a light emitting part forming composition between a plurality of bank portions 100, the bank portions 100 partitioning a pixel unit, and drying the droplets. The bank portions 100 are formed in a different shape from conventional bank portions. That is, stepwise portions 110 of the bank portions 100 are formed in the region in which the droplets 200 are dropped. The bank portions 100 have a cross-sectional configuration which has reduced sidewalls when compared with conventional bank portions. In this way, the space in which the droplets 200 are dropped is enlarged compared to the conventional bank portions. In other words, the bank portions 100 are cut to provide larger spaces to be filled with the droplets 200, so that the droplets 200 do not overflow, and thus the risk of contact between droplets on adjacent pixels is reduced or effectively prevented.

The shape of the bank portions 100 may be obtained using the following processes.

First, a photoresist layer 100′ is formed. The photoresist layer 100′ will eventually be modified to form the bank portions 100. Here, the location of the photoresist layer 100′ can be on an electric circuit layer, such as a TFT layer as described above. The bank portions 100 are formed after electrodes 300, such as an anode or a cathode, are formed.

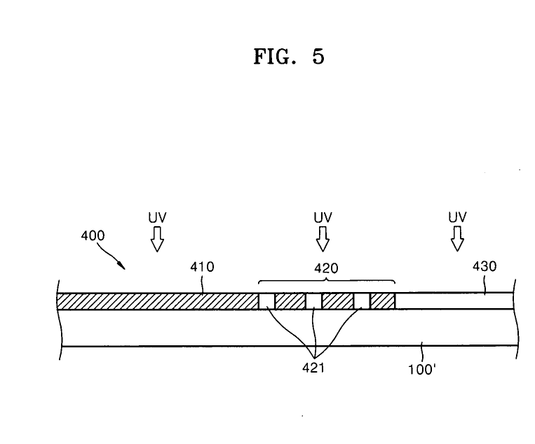

FIG. 5 is a cross-sectional view illustrating an exemplary embodiment of a process of forming a bank portion of the organic light emitting diode illustrated in FIG. 4 according to the present invention. Referring to FIG. 5, a mask 400 is provided to either block or transmit ultraviolet light. The mask 400 has a shadowing region 410, an exposing region 430, and a half-tone region 420, which is an intermediate state between the shadowing region 410 and the exposing region 430. The half-tone region 420 has a plurality of slits 421 to allow intermediate-level exposure. The stepwise portions 110 (refer to FIG. 4) are formed in a region corresponding to the half-tone region 420.

When the mask 400 is provided on the photoresist layer 100′ and exposed to ultraviolet light, the portion of the photoresist layer 100′ corresponding to the shadowing region 410 is not hardened because it is not exposed to light. The portion of the photoresist layer 100′ corresponding to the exposing region 430 is hardened by the ultraviolet light, and the portion of the photoresist layer 100′ corresponding to the half-tone region 420 is hardened to an intermediate level. Therefore, when a developing process is performed, a portion of the photoresist layer 100′ corresponding to the shadowing region 410 is removed forming a pixel space in which the droplet 200 of the light emitting part forming composition can be dropped. The portion of the photoresist layer 100′ corresponding to the exposing region 430 remains to form a central portion of the bank portion 100. The portion of the photoresist layer 100′ corresponding to the half-tone region 420 is only partially removed by the developing process and the part which remains forms the stepwise portion 110 extending from the center of the bank portion 100 toward the light emitting part 200.

Therefore, as the stepwise portion 110 is formed at the end of the bank portion 100 through this process, the space in which the droplet 200 is to be dropped is widened, which prevents droplets 200 on adjacent pixels from contacting each other.

An alternative exemplary embodiment of a process of forming a bank portion of the organic light emitting diode according to the present invention includes a mask with a similar function to that illustrated in FIG. 5. However, a different type of photoresist material may be used so that when a developing process is performed the portion of the photoresist layer 100′ exposed to ultraviolet light is removed. In this process, the portion of the photoresist layer 100′ corresponding to the exposing region 430 is removed forming a pixel space in which the droplet 200 of the light emitting part forming composition can be dropped. The portion of the photoresist layer 100′ corresponding to the shadowing region 410 remains to form a central portion of the bank portion 100. The portion of the photoresist layer 100′ corresponding to the half-tone region 420 is only partially removed by the developing process and the part which remains forms the stepwise portion 110 extending from the center of the bank portion 100 toward the light emitting part 200.

After the formation of the bank portions, the light emitting part may be formed. The light emitting part can include hole transporting layers, emission layers, energy transport layers, electron transport layers, and other similar substances. Such layers can be formed by dropping a dilution of a light emitting part forming material, such as a light emitting material or a hole transporting material, in a solvent into the space between the bank portions as a droplet 200 and drying the droplet 200.

In other words, since droplets are dropped in a wider space than in the prior art, adjacent pixels are prevented from being shorted, and a more reliable and stable organic light emitting diode, which is less prone to malfunction, can be formed.

An organic light emitting diode according to the present invention as described above provides the following advantages.

First, since stepwise portions are formed at the ends of the bank portions 100 to widen the space occupied by the light emitting part, shorting between adjacent pixels is prevented during the depositing and drying of droplets of a light emitting material composition.

Second, as shorting between pixels is prevented, the distance between adjacent pixels may be reduced, thus obtaining a high resolution panel with a denser pixel distribution.

Third, since the space occupied by the light emitting part is widened, a greater number of droplets may be dropped, and thus the concentration of the light emitting part material solute in each of the droplets may be decreased. As a result, plugging of nozzles ejecting the droplets is reduced or effectively prevented.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting diode comprising:
a plurality of bank portions; and
light emitting parts formed between the bank portions,
wherein the bank portions have stepwise portions at ends thereof extending to the light emitting part.

2. The organic light emitting diode of claim 1, wherein the light emitting part comprises an emission layer and a hole transporting layer.

3. A method of manufacturing an organic light emitting diode, comprising:
forming a plurality of bank portions; and
forming light emitting parts between the bank portions,
wherein the forming of the bank portions comprises;
forming a photoresist layer;
preparing a mask having an exposing region, a shadowing region, and slits between the exposing region and the shadowing region;
exposing the photoresist layer to an ultraviolet light source through the mask; and
developing the exposed photoresist layer to form bank portions having stepwise portions in a region corresponding to the slits.

4. The method of claim 3, wherein the forming of the light emitting parts comprises depositing a dilution of a light emitting part forming material in a solvent between the stepwise portions of the bank portions as a droplet and drying the droplet.
